(19) United States
(12) Patent Application Publication
(10) Pub. No.: US 2004/0090350 A1
(43) Pub. Date: May 13, 2004

(54) Infrared transmitting frame on a back holder of a keyboard

(76) Inventor: Chien Yi Yang, Taipei (TW)

Correspondence Address: John S. Egbert, Harrison & Egbert, 412 Main Street, 7th Floor, Houston, TX, 77002, US

(21) Appl. No.: 10/361,172

(22) Filed: Feb. 10, 2003

(30) Foreign Application Priority Data
Oct. 29, 2002 (TW) 091217337

(51) Int. Cl. H03M 11/00

(52) U.S. Cl. 341/22

(57) ABSTRACT

An infrared transmitting frame on a back holder of a keyboard includes an infrared transmitting frame disposed on a back holder of a keyboard; wherein the transmitting frame has a set of swivel discs fixed on the back holder; a link is pivotally disposed on the swivel disc by a shaft pin for lifting upwardly; the link has a plurality of segments; the segments are connected by shafts to be bendable; a distal end of the link is a fixing seat provided for an infrared transmitter; wherein the infrared transmitter has a conducting wire disposed along the link, passing the swivel disc and connecting into a guide slot and further into a main body of the keyboard. The present invention is characterized that the swivel disc allows the infrared transmitting frame to be adjusted to any projecting angle within 360° so as to accommodate the application of personal digital assistants in various types.

### RELATED U.S. APPLICATIONS

Not applicable.

### STATEMENT REGARDING FEDERALLY SPONSORED RESEARCH OR DEVELOPMENT

Not applicable.

### REFERENCE TO MICROFICHE APPENDIX

Not applicable.

### FIELD OF THE INVENTION

The present invention relates to an infrared transmitting device on a keyboard of a personal digital assistant (PDA).

### BACKGROUND OF THE INVENTION

The present invention of an infrared transmitting device on a keyboard of a personal digital assistant (PDA) is an innovative device capable of synchronously transmitting infrared signals toward a top plane and two lateral planes of a PDA as well as accommodating most of the currently available PDA in various types.

### BRIEF SUMMARY OF THE INVENTION

The main feature of the present invention is that an infrared transmitting frame is pivotally disposed on an upper end of an engaged back holder; a set of swivel discs connect the transmitting frame and the back holder; a conducting wire extends upwardly to an infrared transmitter located at a top end of the transmitting frame along the back holder, the swivel disc and the transmitting frame. The transmitter transmits signals toward a receiver of the PDA.

To enable a further understanding of an embodiment of the present invention, the brief description of the drawings is followed by the detailed description of a preferred embodiment.

### BRIEF DESCRIPTION OF THE SEVERAL VIEWS OF THE DRAWINGS

FIG. 1 is a pictorial drawing of the embodiment and a schematic drawing of the application of the present invention.

FIG. 2 is the first pictorial drawing of the embodiment of the present invention.

FIG. 3 is the second pictorial drawing of the embodiment of the present invention.

FIG. 4 is the third pictorial drawing of the embodiment of the present invention.

FIG. 5 is a pictorial and exploded drawing of the present invention shown in FIG. 3.

FIG. 6 is a partial pictorial and exploded drawing of the present invention of shown in FIG. 2.

FIG. 7 is a two-view drawing (including a longitudinal and a later, cross-sectional drawings) of the present invention shown in FIG. 2.

### DETAILED DESCRIPTION OF THE INVENTION

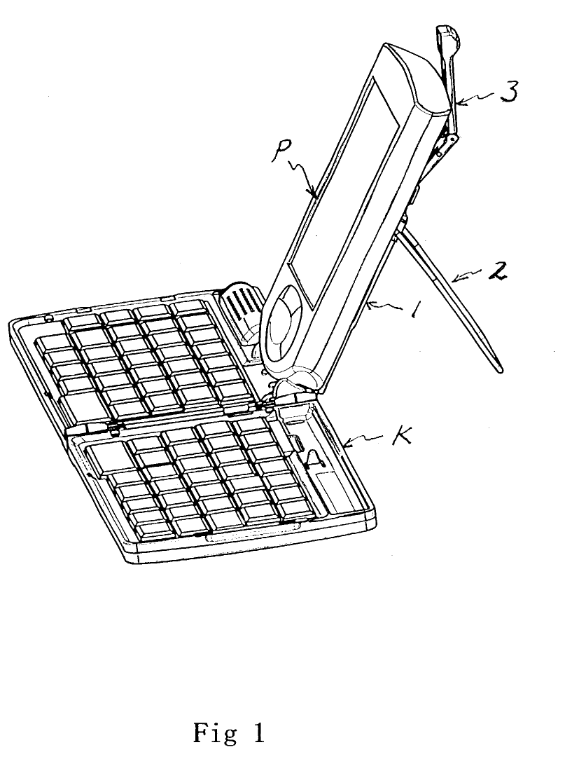

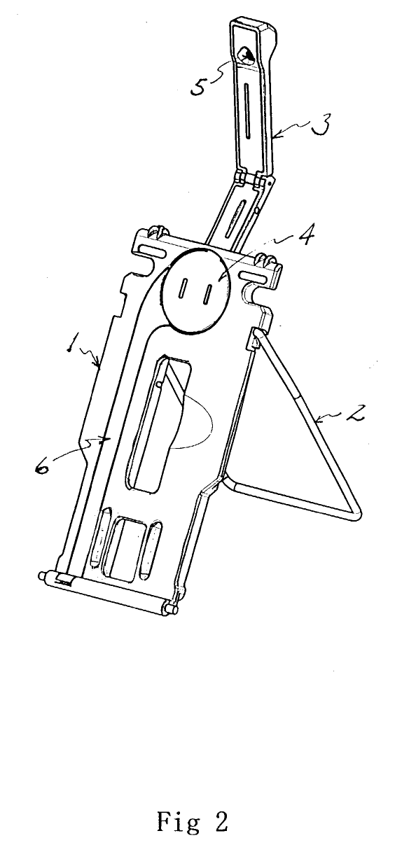

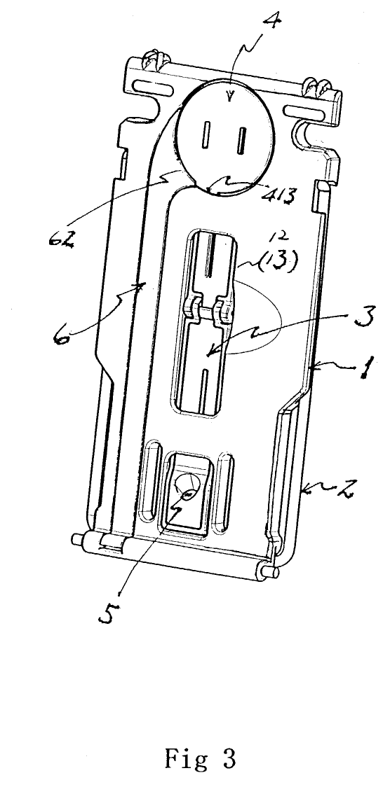

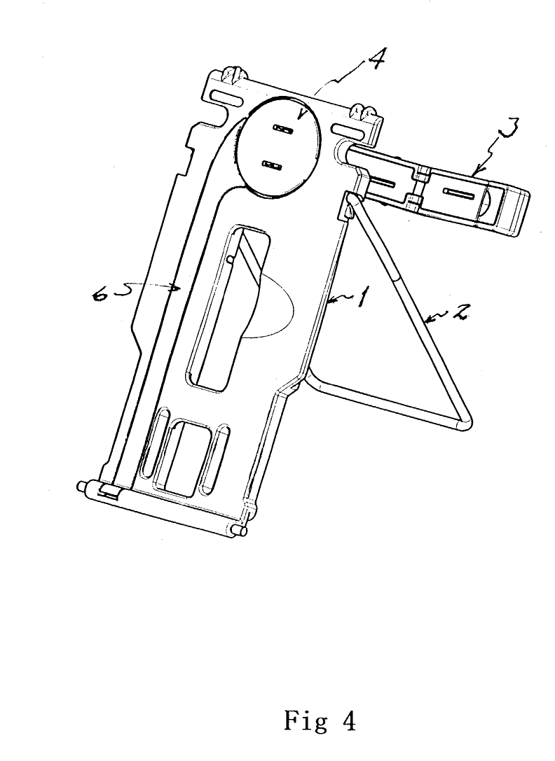

As indicated in FIG. 1, the present invention is an infrared transmitting device for a keyboard (K) of a personal digital assistant (PDA). It is mainly mounted on a back holder (1) of the keyboard (K) and connects with the back holder (1) via a set of swivel discs (4), as shown in FIG. 2. A link (3), or the infrared transmitting frame, disposed on the swivel disc (4) is capable of transmitting the light toward any fixed point within a 360° rotation space. As indicated in FIG. 4, when the link (3) turns to a 90° angle for positioning, it transmits signals to a PDA disposed with an infrared receiver on the lateral side thereof. As indicated in FIG. 3, the link (3) turns to a downward position after a support (2) presses against the back portion of the back holder (1); therefore, the link (3) presses and inserts into a longitudinal insert slot (13) disposed on the back side of the back holder (1). The middle segment of the insert slot (13) is disposed with a communicated center hole (12) such that an user presses the link (3) at this area to withdraw it from the insert slot (13) as the lead action of activating the transmitting device.

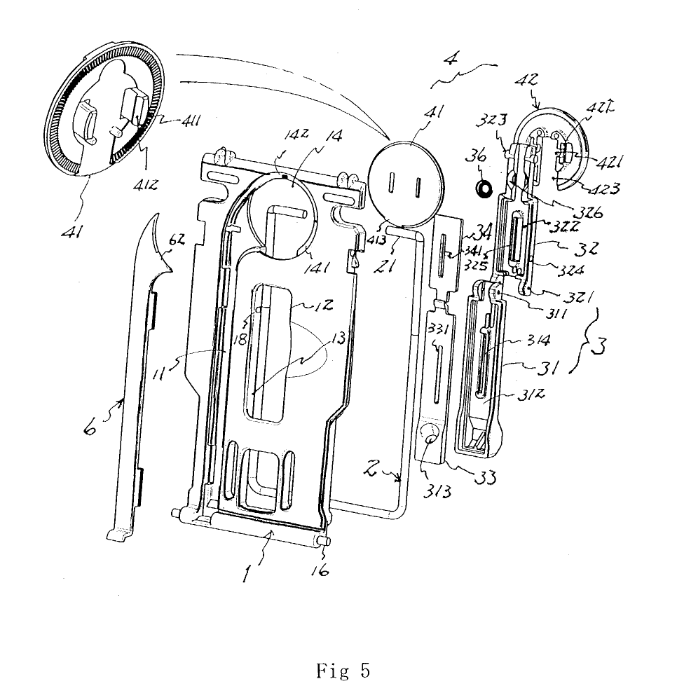

FIG. 5 shows the detail structure of the components of the present invention; wherein the back holder (1) is of a long plate body disposed with a pair of turning shafts (16) on two lateral sides of a bottom end thereof, the turning shafts (16) are pivotally connected with a main body of the keyboard (K). The center of a top end of the back holder (1) is disposed with a communicated swivel disc hole (14); a convex rim (141) is disposed on the central periphery of the swivel disc hole (14); mountain-shaped positioning teeth (142) are disposed on the convex rim (141); the back side of the back holder (1) extends downwardly from the swivel disc hole (14) to form the insert slot (13); the middle segment of the insert slot (13) is disposed with the central hole (12) communicating the front and back sides of the back holder (1). The front side of the back holder (1) extends downwardly from the lateral side of the swivel disc hole (14) to form a guide slot (11) for inserting a guide wire of an infrared transmitter. The insert slot (13) is for hiding the insertion of the link (3). Furthermore, the swivel disc (4) comprises a united upper swivel disc (41) and a lower swivel disc (42). Mountain-shaped positioning teeth (411) are disposed radiantly on the periphery of the inner side of the upper swivel disc (41) to match with the positioning teeth (142) inside the swivel disc hole (14) on the back holder (1) for meshing and positioning. A tenon slot (412) is disposed on the upper swivel disc (41) to correspond to a retaining tenon (422) on the lower swivel disc (42). The center of the lower swivel disc (42) is a reverse U-shaped link slot (423); left and right walls of the link slot (423) are disposed with a pair of transverse shaft cavities (421). The link (3) is assembled by two or more segments; each segment bends to a certain degree for adjusting the projecting angle of the infrared transmitter disposed on the link (3); the link (3) shown in FIG. 5 has two segments including an upper link (31) and a lower link (32); both of the upper and lower links (31, 32) have U-shaped cross sections; the lower end portion of the lower link (32) is a transverse turning shaft (323) to insert with the shaft cavity (421) on the lower swivel disc (42). The center of the upper link (31) is a slot (312) with openings disposed at the front side and the lower end thereof to engage with a vertically communicated slot (322) at the center of the lower link (32). The slots on the front sides of two links (31, 32) are sealed respectively by an upper link cover (33) and a lower link cover (34) thereby forming a hidden slot communicated vertically for distributing the conducting wire. An upper end on the front sides of the upper link cover (33) slants forward to penetrate a hole (313) of the infrared transmitter for inserting the infrared transmitter. The adjacent ends of the upper and lower link (31, 32) are disposed with shaft holes (311, 321) pivotally connected by shaft pins (35) for bending at a certain degree. A bendable copper wire or aluminum strip is respectively embedded inside the slots (312, 322) between the upper and lower links (31, 32) to bridge over the upper and lower links (31, 32) thereby assisting them to bend at any angle for positioning.

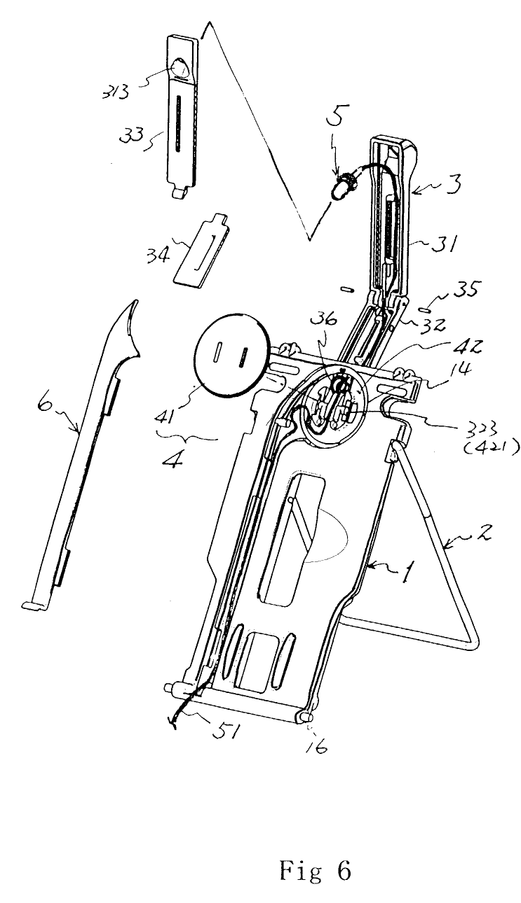

As indicated in FIG. 6, the distal end of the link (3) is pivotally disposed on the shaft cavity (421) of the lower swivel disc (42) via a shaft (323); the lower swivel disc (42) inserts into the swivel disc hole (14) from the back side of the back holder (1); in the swivel disc hole (14) on the front side of the back holder (1), the upper swivel disc (41) fixedly clips with the lower swivel disc (42) thereby inserting the transmitting device including the link (3) on the back holder (1) such that the assembled device is capable of using the swivel disc (4) as the shaft to rotate within 360°. The infrared transmitter (5) is disposed at the upper end of the link (3); the guide wire (51) thereof inserts downwardly along the slots (312, 322) on the link (3). The clipped upper and lower swivel discs (41, 42) of the swivel disc (4) form an isolated space in between by the convex rim of the swivel disc hole (14); the guide wire (51) winds around this space, bends into the guide slot (11) on the back holder (1) and connects the keyboard (K) downwardly along the guide slot (11). After the guide wire (51) is embedded, it is completely covered by a guide slot cover (6), an upper link cover (33) and a lower link cover (34).

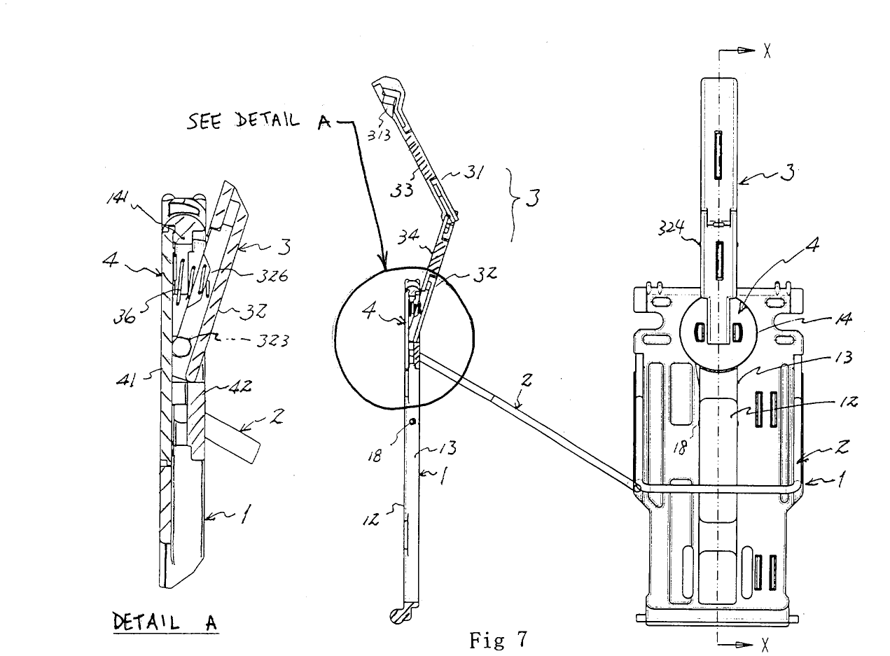

After the assembly, the link (3) of the transmitting device is turned to the upper most end, as shown in FIG. 7; wherein a spring cavity (326) is disposed at the upper aspect of the turning shaft (323) at the bottom end of the lower link (32) for inserting a spring (36); the other side of the spring (36) pushes against the inner side of the upper swivel disc (41) so as to make the link (3) keep a certain elevation angle for positioning the swivel disc (4) without being influenced by another force. As indicated in the drawing of the back side view thereof, the left and right sides of the middle segment of the link (3) are disposed with a pair of convex tenons (324); a tenon cavity (18) is disposed at the opposite position of the insert slot (13) on the back holder (1). When the link (3) turns back to its lower starting point and presses to insert into the insert slot (13), the convex tenon (324) inserts into the tenon cavity (18) thereby fixing the link (3) on the back holder (1), as shown in FIG. 3.

The infrared transmitting device on a back holder of a keyboard provides signal transmission for the PDA in various types having the infrared receiver disposed on the left side, the right side and the upper aspect of the PDA keyboard; wherein all of the structural members are bendable for completely leaning against and hiding in the back holder; the back holder further folds into the inner portion of the keyboard thereby making the collection of the keyboard very smooth and beautiful.

It is of course to be understood that the embodiment described herein is merely illustrative of the principles of the invention and that a wide variety of modifications thereto may be effected by persons skilled in the art without departing from the spirit and scope of the invention as set forth in the following claims.

I claim:

1. An infrared transmitting frame on a back holder of a keyboard comprises a infrared transmitting frame disposed on a back holder of a keyboard; wherein the transmitting frame has a set of swivel discs fixed on the back holder; wherein a link is pivotally disposed on the swivel disc by a shaft pin for lifting upwardly; the link has a plurality of segments; the segments are connected by shafts to be bendable; a distal end of the link is a fixing seat provided for an infrared transmitter; wherein the infrared transmitter has a conducting wire disposed along the link, passing the swivel disc and connecting into a guide slot and further into a main body of the keyboard; the present invention is characterized that the swivel disc allows the infrared transmitting frame to be adjusted to any projecting angle within 360° so as to accommodate the application of personal digital assistants in various types.

2. An infrared transmitting frame on a back holder of a keyboard according to claim 1, wherein a bendable copper wire or aluminum strip is embedded respectively inside the slots between the upper and lower links to bridge over the upper and lower links thereby assisting them to bend at any angle for positioning.
